(19) United States
(12) Patent Application Publication
(10) Pub. No.: US 2024/0196568 A1
(43) Pub. Date: Jun. 13, 2024

(54) SEMICONDUCTOR MEMORY DEVICE

(71) Applicant: KIOXIA CORPORATION, Tokyo (JP)

(72) Inventor: Akihito ISHIMURA, Tokyo (JP)

(73) Assignee: KIOXIA CORPORATION, Tokyo (JP)

(21) Appl. No.: 18/584,427

(22) Filed: Feb. 22, 2024

Related U.S. Application Data
(63) Continuation of application No. PCT/JP2021/045758, filed on Dec. 13, 2021.

(30) Foreign Application Priority Data
Aug. 25, 2021 (JP) 2021-137113

(51) Int. Cl. H05K 7/20; H01L 25/065; H01L 25/18; H05K 1/18; H10B 80/00

(52) U.S. Cl. CPC H05K 7/205; H01L 25/0652; H01L 25/18; H10B 80/00; H01L 2225/06562; H01L 2225/06582; H05K 1/18; H05K 2201/10189

(57) ABSTRACT

A semiconductor memory device includes a substrate, a plurality of memory chips, a controller, a plurality of terminals, a sealing member, and a sheet. The substrate has a first plane and a second plane positioned on an opposite side of the first plane. The plurality of memory chips are mounted on the first plane of the substrate. The controller is mounted on the first plane of the substrate to control the plurality of memory chips. The plurality of terminals provided on the second plane of the substrate and including a plurality of test terminals. The sealing member seals the first plane of the substrate, the plurality of memory chips, and the controller. The sheet covers the plurality of test terminals among the plurality of terminal. The sheet is an insulator and has a thermal conductivity of from 1.0 W/(m·K) to 8.0 W/(m·K).

### CROSS-REFERENCE TO RELATED APPLICATIONS

This is a continuation application of PCT International Application No. PCT/JP2021/045758 filed on Dec. 13, 2021, designating the United States of America, which is based on and claims priority of Japanese Patent Application No. 2021-137113 filed on Aug. 25, 2021. The entire disclosures of the above-identified applications, including the specifications, drawings and claims are incorporated herein by reference in their entirety.

### BACKGROUND

### Field

Embodiments described herein relate generally to a semiconductor memory device.

### Description of the Related Art

There has been known a semiconductor memory device that includes a substrate, a plurality of memory chips and a controller mounted on a surface on one side of the substrate, and a plurality of terminals provided on a surface on the other side of the substrate.

### BRIEF DESCRIPTION OF THE DRAWINGS

FIG. 1A, FIG. 1B, and FIG. 1C are views exemplarily illustrating an outer shape of a semiconductor memory device according to a first embodiment;

FIG. 2 is a view illustrating an exemplary configuration of the semiconductor memory device;

FIG. 3 is a plan view illustrating an outer shape of a connector to which the semiconductor memory device is mounted and an exemplary arrangement of a region in contact with a sheet;

FIG. 4 is a side view illustrating a state where the semiconductor memory device is set to the connector;

FIG. 5 is a side view illustrating a state where the semiconductor memory device is mounted (connected) to the connector;

FIG. 6 is a plan view illustrating a second main surface on which a plurality of terminals and a sheet of a semiconductor memory device according to a second embodiment are arranged;

FIG. 7 is a plan view illustrating an outer shape of a connector to which the semiconductor memory device is mounted and an exemplary arrangement of a region in contact

FIG. 8 is a plan view illustrating a second main surface on which a plurality of terminals and a sheet of a semiconductor memory device according to a third embodiment are arranged; with a sheet.

FIG. 9 is a plan view illustrating an outer shape of a connector to which the semiconductor memory device is mounted and an exemplary arrangement of a region in contact with a sheet;

FIG. 10 is a plan view illustrating a second main surface on which a plurality of terminals and a sheet of a semiconductor memory device according to a fourth embodiment are arranged;

FIG. 11 is a plan view illustrating an outer shape of a connector to which the semiconductor memory device is mounted and an exemplary arrangement of a region in contact with a sheet;

FIG. 12 is a plan view illustrating a second main surface on which a plurality of terminals and a sheet of a semiconductor memory device according to a fifth embodiment are arranged;

FIG. 13 is a plan view illustrating an outer shape of a connector to which the semiconductor memory device is mounted and an exemplary arrangement of a region in contact with a sheet;

FIG. 14 is a plan view illustrating a second main surface on which a plurality of terminals and a sheet of a semiconductor memory device according to a sixth embodiment are arranged; and

FIG. 15 is a plan view illustrating an outer shape of a connector to which the semiconductor memory device is mounted and an exemplary arrangement of a region in contact with a sheet.

### DETAILED DESCRIPTION

A semiconductor memory device according to one embodiment includes a substrate, a plurality of memory chips, a controller, a plurality of terminals, a sealing member, and a sheet. The substrate has a first plane and a second plane positioned on an opposite side of the first plane. The plurality of memory chips are mounted on the first plane of the substrate. The controller is mounted on the first plane of the substrate to control the plurality of memory chips. The plurality of terminals are provided on the second plane of the substrate and include a plurality of test terminals. The sealing member seals the first plane of the substrate, the plurality of memory chips, and the controller. The sheet covers the plurality of test terminals among the plurality of terminal. The sheet is an insulator and has a thermal conductivity of from 1.0 W/(m·K) to 8.0 W/(m·K).

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments and modifications are attached by same reference numerals and their descriptions may be omitted.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of an X-direction, a Y-direction, and a Z-direction, which are described later and need not correspond to these directions.

Expressions such as “above” and “below” in this specification are based on the substrate to which the semiconductor memory device is mounted. For example, when the above-described first direction intersects with a surface of the substrate, a direction away from the substrate along the first direction is referred to as above and a direction approaching the substrate along the first direction is referred to as below. A lower surface and a lower end of a certain configuration mean a surface and an end portion on the substrate side of this configuration. An upper surface and an upper end of a certain configuration mean a surface and an end portion on a side opposite to the substrate of this configuration. A portion intersecting with the first direction or the second direction is referred to as an edge portion, and a plane intersecting with the first direction or the second direction is referred to as an end surface, a side surface, and the like.

As used herein, “the semiconductor memory device” includes a non-volatile memory, and a controller that controls the non-volatile memory. The semiconductor memory device is a memory device for storage configured to be able to read and write data to and from the non-volatile memory. The semiconductor memory device may be implemented as, for example, a memory card or a solid state drive (SSD). In this case, these memory card and/or SSD may be used as a storage for various information processing apparatuses functioning as various host devices such as a personal computer, a mobile device, a video recorder, and an in-vehicle device.

### First Embodiment

### Outer Shape of Semiconductor Memory Device

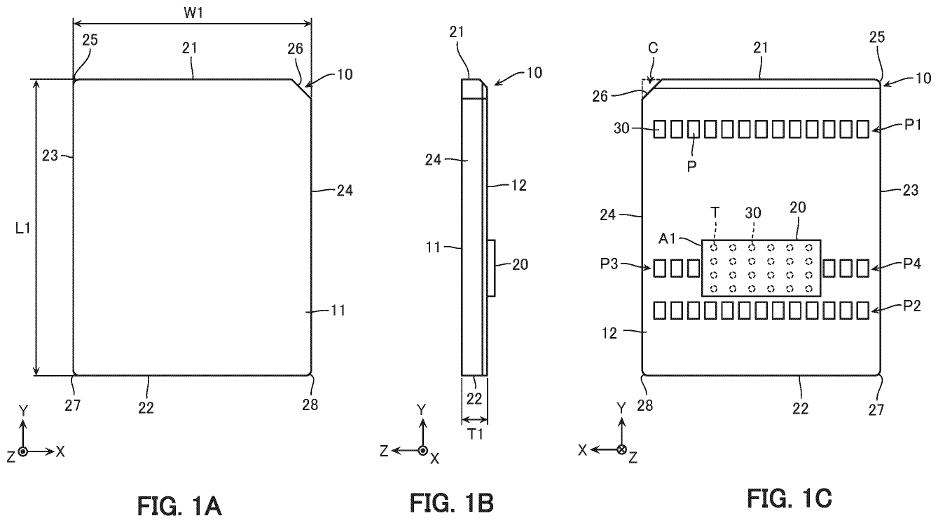

FIG. 1A, FIG. 1B, and FIG. 1C are views exemplarily illustrating an outer shape of a semiconductor memory device according to a first embodiment.

The semiconductor memory device according to the first embodiment has a card shape, and may function as an SSD mountable to a connector in a host device. The connector to which the semiconductor memory device according to this embodiment is mounted may be, for example, a connector of hinge type. The connector may be push-pull type or push-push type. In this embodiment, it is assumed that the semiconductor memory device is mounted to the connector of hinge type, but the embodiment is not limited thereto.

In the following, the semiconductor memory device may be referred to as the memory device.

FIG. 1A is a plan view indicating one surface of a memory device 10. FIG. 1B is a side view illustrating one side surface of the memory device 10. FIG. 1C is a plan view indicating one surface of the memory device 10, and is a plan view indicating the other surface positioned on an opposite side of the one surface illustrated in FIG. 1A.

As illustrated in FIG. 1A to FIG. 1C, in this specification, an X-axis, a Y-axis, and a Z-axis are defined as follows. These X-axis, Y-axis, and Z-axis are perpendicular to one another. The X-axis is along a width direction of the memory device 10. The Y-axis is along a length direction of the memory device 10. The Z-axis is along a thickness direction of the memory device 10. In this specification, a view in which the memory device 10 and a connector 50 (see FIG. 3 and the like) to which the memory device 10 is mounted is referred to as in a plan view when viewed from a direction of the Z-axis.

The memory device 10 is a semiconductor memory device configured to operate with an externally applied power supply voltage.

As illustrated in FIG. 1A, FIG. 1B and FIG. 1C, the memory device 10 has, for example, an outer shape of a rectangular card shape with a first width W1 in the X-direction, a first length L1 in the Y-direction, and a first thickness T1 in the Z-direction. The first length L1 is greater than the first width W1. The first width W1, the first length L1, and the first thickness T1 may be, for example, 14±0.10 mm, 18±0.10 mm and 1.4±0.10 mm, respectively.

As illustrated in FIG. 1A, FIG. 1B and FIG. 1C, the memory device 10 has a rectangular first main surface 11 and a rectangular second main surface 12 spaced from one another in the Z-direction and extending in the X-direction and the Y-direction. The memory device 10 has a rectangular first end surface 21 and a rectangular second end surface 22 spaced from one another in the Y-direction and extending in the X-direction and the Z-direction. The first end surface 21 is provided between one end edges in the Y-direction of the first main surface 11 and the second main surface 12. The second end surface 22 is provided between the other end edges in the Y-direction of the first main surface 11 and the second main surface 12. The memory device 10 has a rectangular first side surface 23 and a rectangular second side surface 24 spaced from one another in the X-direction and extending in the Y-direction and the z-direction. The first side surface 23 is provided between one end edges in the X-direction of the first main surface 11 and the second main surface 12. The second side surface 24 is provided between the other end edges in the X-direction of the first main surface 11 and the second main surface 12.

The memory device 10 has a first corner portion 25 at a connecting portion of the first end surface 21 and the first side surface 23, a second corner portion 26 at a connecting portion of the first end surface 21 and the second side surface 24, a third corner portion 27 at a connecting portion of the second end surface 22 and the first side surface 23, and a fourth corner portion 28 at a connecting portion of the second end surface 22 and the second side surface 24.

The first corner portion 25, the third corner portion 27, and the fourth corner portion 28 are, for example, R-chamfered, such as R0.2. The second corner portion 26 is different from the other corner portions 25, 27, 28 for determination of front and back surfaces. For example, an angular chamfer such as C1.1 is provided.

### Configuration of Semiconductor Memory Device

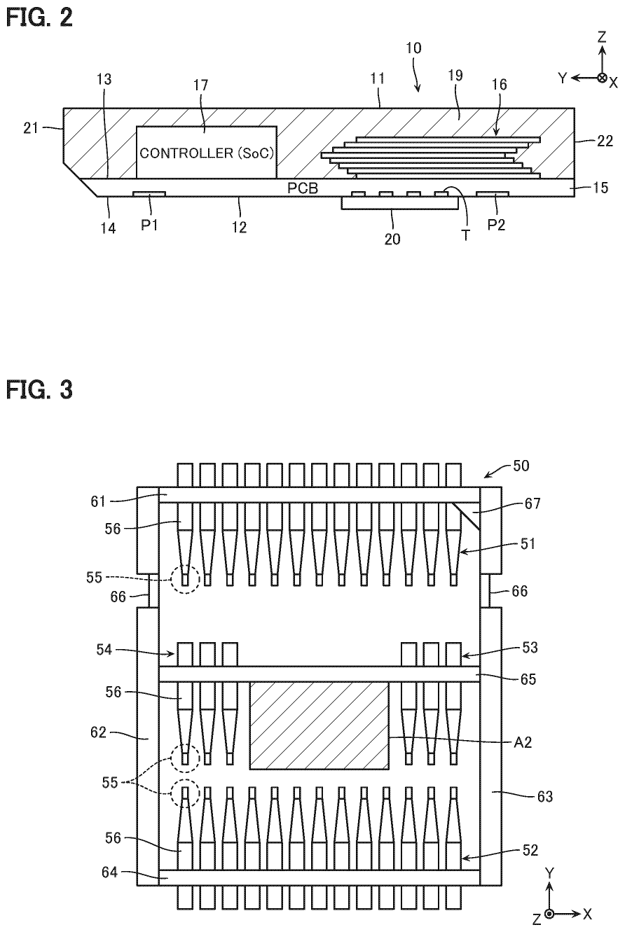

FIG. 2 is a view illustrating an exemplary configuration of the memory device 10.

As illustrated in FIG. 2, the memory device 10 includes a printed circuit board 15, and a NAND flash memory 16 and a controller 17 mounted on the printed circuit board 15. The NAND flash memory 16 and the controller 17 are mounted on a first plane (upper surface) 13 of the printed circuit board 15. As illustrated, a second plane (lower surface) 14 of the printed circuit board 15 may be flush with the second main surface 12 of the memory device 10.

The NAND flash memory 16 may include a plurality of stacked NAND flash memory chips. These plurality of NAND flash memory chips may be configured to be able to perform an interleave operation. The controller 17 may be an LSI including a system on a chip (SoC). The controller 17 controls the NAND flash memory 16 and the entire memory device 10 including the NAND flash memory 16. The controller 17 can perform, for example, read/write control for the NAND flash memory 16 and communication control with outside. In addition, the memory device 10 has a PCIe interface as a system interface, and in the memory device 10, the communication control may be performed by a protocol such as NVM Express (NVMe) (trademark) compliant with PCIe standard.

The NAND flash memory 16, the controller 17, and the first plane 13 of the printed circuit board 15 are entirely covered and completely sealed with, for example, a mold resin 19 as a sealing member. Thus, the memory device 10 is realized as a package (memory package) having a card shape.

### Exemplary Arrangement of Terminals

As illustrated in FIG. 1C, a plurality of terminals 30 are provided in the second main surface 12 of the memory device 10 (the second plane 14 of the printed circuit board 15). These plurality of terminals 30 may also be referred to as pins or pads. The plurality of terminals 30 include a plurality of signal terminals P and a plurality of test terminals T. The plurality of signal terminals P include a plurality of first signal terminals P1, a plurality of second signal terminals P2, a plurality of third signal terminals P3, and a plurality of fourth signal terminals P4.

The plurality of first signal terminals P1 are closer to the first end surface 21 than the plurality of second signal terminals P2, and are arranged at first intervals with one another in the X-direction. The plurality of second signal terminals P2 are closer to the second end surface 22 than the plurality of first signal terminals P1, and are arranged at second intervals with one another in the X-direction. A distance in the Y-direction between the plurality of first signal terminals P1 and the plurality of second signal terminals P2 is longer than a distance in the Y-direction between the plurality of first signal terminals P1 and the first end surface 21 and longer than a distance in the Y-direction between the plurality of second signal terminals P2 and the second end surface 22.

The plurality of third signal terminals P3 and the plurality of fourth signal terminals P4 are provided between the plurality of first signal terminals P1 and the plurality of second signal terminals P2. A distance in the Y-direction between the plurality of third signal terminals P3 with the plurality of fourth signal terminals P4 and the plurality of first signal terminals P1 is larger than a distance in the Y-direction between the plurality of third signal terminals P3 with the plurality of fourth signal terminals P4 and the plurality of second signal terminals P2.

The plurality of third signal terminals P3 are arranged at third intervals with one another in the X-direction. The plurality of fourth signal terminals P4 are arranged at fourth intervals with one another in the X-direction. The number of the plurality of third signal terminals P3 is less than the number of the plurality of first signal terminals P1 and less than the number of the plurality of second signal terminals P2. The number of the plurality of fourth signal terminals P4 is also less than the number of the plurality of first signal terminals P1 and less than the number of the plurality of second signal terminals P2. Test terminals T are provided between the plurality of third signal terminals P3 and the plurality of fourth signal terminals P4. Note that the first distance to the fourth distance may be all the same or different.

The first signal terminals P1 may include, for example, two lanes of signal terminals for a high-speed serial interface, such as PCI Express (Registered trade mark) (PCIe). The signal terminals P corresponding to one lane may include two terminals of a receiver differential signal pair and two terminals of a transmitter differential signal pair. The two differential terminals may be surrounded by a ground terminal. Although not illustrated, for example, a PCIe lane may be added between the first signal terminals P1 and the second signal terminals P2.

The third signal terminals P3 and the fourth signal terminals P4 may include, for example, signal terminals for arbitrary optional signals that varies from product to product. Examples of the signal terminals for the optional signals may include signal terminals for, for example, a sideband signal (SMBus signal, WAKE #signal, and PRSNT #signal) conforming to a PCIe standard, a ground terminal, and the like. Examples of the sideband signal conforming to the PCIe standard may include a CLKREF signal pair, a CLKREQ #signal, a PERST #signal, and the like. At least a part of the third signal terminals P3 and the fourth signal terminals P4 do not have to be a signal terminal that is essential for the memory device 10. In other words, it may be an optional signal terminal for the memory device 10. Thus, the number of the third signal terminals P3 and the fourth signal terminals P4 may be less than the number of the first signal terminals P1 and the second signal terminals P2. Note that the sideband signal in this embodiment may be referred to as an optional signal.

The second signal terminals P2 may include, for example, control signals used in common for each product and terminals for power supply. The second signal terminals P2 may mainly include a signal terminal for a differential clock signal, a signal terminal for a common PCIe sideband signal, a power supply terminal, and other signal terminals.

On the other hand, the plurality of test terminals T are electrically connected to, for example, the controller 17 and are used to perform a test for screening a non-defective device of the memory device 10.

The plurality of test terminals T are arranged outside a region where the plurality of signal terminals P are arranged. In this embodiment, the plurality of test terminals T are arranged in, for example, a region between the first signal terminals P1 and the second signal terminals P2 and between the third signal terminals P3 and the fourth signal terminals P4. For example, the plurality of test terminals T are arranged at equal intervals in each of four rows in the Y-direction and six columns in the X-direction.

In the second main surface 12 (the second plane 14 of the printed circuit board 15) of the memory device 10, a thermal interface material (TIM) 20 as a mask sheet is bonded to a portion where these plurality of test terminals T are provided. The plurality of test terminals T are covered by the TIM 20 and are in contact with the TIM 20. Hereinafter, the region of the memory device 10 where the TIM 20 is bonded is referred to as “bonded region A1”. As the TIM 20, a material having an excellent thermal conductivity, an insulating property, a flexibility, and a heat resistance can be used. As the TIM 20, for example, one having a higher thermal conductivity than a thermal conductivity of polycarbonate is used. The thermal conductivity of the polycarbonate is of an order of 0.2 W/(m·K). As the TIM 20, for example, one having a thermal conductivity of an order of from 1.0 W/(m·K) to 8.0 W/(m·K) may be used. Further, as the TIM 20, one having a thermal conductivity larger than 8.0 W/(m·K) may be used. As the TIM 20, for example, one having a higher insulating property than an insulating property of carbon graphite is used.

Note that the shapes, the arrangements, and the like of the terminals 30 described above are merely examples, and the lengths in the Y-direction of the plurality of terminals 30 do not have to be all the same.

### Configuration of Connector

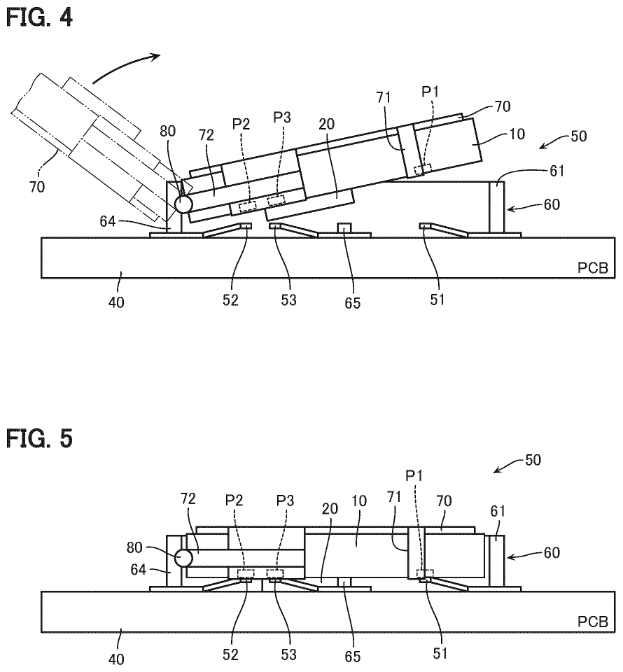

FIG. 3 is a plan view illustrating an outer shape of the connector 50 provided on the host device to which the memory device 10 is mounted and an exemplary arrangement of a contact region A2 in contact with the TIM 20. The memory device 10 is mounted from an upper side of the connector 50 illustrated in FIG. 3 with the terminal surface (the second main surface 12) side illustrated in FIG. 1C facing downward. FIG. 4 is a side view illustrating a state where the memory device 10 is set to the connector 50 prior to mounting (connecting) of the memory device 10. FIG. 5 is a side view illustrating a state where the memory device 10 is mounted (connected) to the connector 50. As illustrated in FIGS. 4 and 5, in this the embodiment, the connector 50 of hinge type is used.

As illustrated in FIGS. 3 to 5, the connector 50 to which the memory device 10 is mounted is provided on a printed circuit board 40 of the host device and includes a plurality of lead frames 51, 52, 53, and 54. These plurality of lead frames 51 to 54 are arranged to correspond to the signal terminals P1, P2, P3, and P4 of the memory device 10, respectively. Each of the lead frames 51 to 54 forms a spring lead in which tip sides thereof are bent away from the printed circuit board 40 with respect to base sides thereof.

In the example of FIG. 3, the lead frames 51 to 54 are arranged to have their respective longitudinal directions along the Y-direction. The lead frames 51, 53 and 54 have contact portions 55 at the tips thereof, which are to be connected to the signal terminals P1, P3, and P4, oriented to a side of the lead frames 52 in the Y-direction. The lead frames 52 have the contact portions 55 at the tips thereof, which are to be connected to the signal terminals P2, oriented to a side of the lead frames 51, 53 and 54 in the Y-direction. That is, the tips of the lead frames 53 and 54 face the tips of the lead frames 52 in the Y-direction. The lead frames 51 to 54 have the same lengths in the Y-direction. However, the direction of the lead frames 51 to 54 and/or the lengths in the Y-direction are not limited thereto. For example, the lengths in the Y-direction of the lead frames 51 to 54 may be different one another.

The connector 50 includes a connector frame 60 and a lid portion 70 openably and closably connected to the connector frame 60 via a hinge 80. The connector frame 60 secures the lead frames 51 to 54 and supports the memory device 10 when the memory device 10 is mounted. The connector frame 60 houses the memory device 10 and positions the memory device 10 with respect to the lead frames 51 to 54 when the memory device 10 is mounted to the connector 50.

As illustrated in FIG. 3, the connector frame 60 includes a first wall portion 61, a second wall portion 62, a third wall portion 63, a fourth wall portion 64, a connecting portion 65, cutout portions 66, and a corner guide portion 67.

The first wall portion 61 extends in the X-direction. The first wall portion 61 contacts the first end surface 21 of the memory device 10 when the memory device 10 is mounted. The first wall portion 61 supports mounting portions 56 on base sides of the lead frames 51 by bonding or the like.

The second wall portion 62 extends in the Y-direction. The second wall portion 62 contacts the first side surface 23 of the memory device 10 when the memory device 10 is mounted.

The third wall portion 63 extends in the Y-direction. The third wall portion 63 contacts the second side surface 24 of the memory device 10 when the memory device 10 is mounted.

The fourth wall portion 64 extends in the X-direction. The fourth wall portion 64 contacts the second end surface 22 of the memory device 10 when the memory device 10 is mounted. The fourth wall portion 64 supports the mounting portions 56 on base sides of the lead frames 52 by bonding or the like.

The connecting portion 65 extends in the X-direction and connects the second wall portion 62 and the third wall portion 63 at a position between the first wall portion 61 and the fourth wall portion 64. The connecting portion 65 supports the mounting portions 56 on base sides of the lead frames 53 and 54 by bonding or the like.

The corner guide portion 67 prevents the memory device 10 from being mounted in a wrong direction to the connector frame 60. The corner guide portion 67 conforms to the second corner portion 26 of the memory device 10 when the memory device 10 is mounted in a correct direction to the connector frame 60.

The lid portion 70 houses the memory device 10 in a state the memory device 10 is opened at 90° to 180° with respect to the printed circuit board 40, as illustrated by the two-dot chain line in FIG. 4. The lid portion 70 has a guide portion 72 for positioning the memory device 10 provided in a vicinity of the hinge 80, and claw portions 71 provided at positions away from the hinge 80. The cutout portions 66 are formed on the second wall portion 62 and the third wall portion 63 of the connector frame 60. The cutout portions 66 are coupled to the claw portions 71 of the lid portion 70 in a state the lid portion 70 is closed (see FIGS. 4 and 5).

The contact region A2 of the printed circuit board 40, illustrated by hatched lines in FIG. 3, contacts the TIM 20 bonded to the bonded region A1 of the memory device 10 when the memory device 10 is mounted to the connector 50.

As illustrated in FIG. 3, the contact region A2 is arranged on the printed circuit board 40 on which the connector 50 is mounted, avoiding the plurality of lead frames 52 to 54 and the connecting portion 65. More specifically, for example, the contact region A2 is provided between the lead frames 53 and the lead frames 54. The contact region A2 is provided between the plurality of lead frames 52 and the connecting portion 65.

In the contact region A2 of the printed circuit board 40, a solid pattern having a good thermal conductivity may be formed. The solid pattern may be connected to a ground pattern.

### Effects of First Embodiment

In the memory device, calorific value increases with improvement of operating speed. For this reason, for example, in an SSD or the like, a heat sink is provided on a side of the mounting substrate where the memory device is mounted, and this heat sink also cools the memory device. However, it may be difficult to use the heat sink when the memory device is used in environment with strict height restrictions.

In the first embodiment, the signal terminals P arranged in the memory device 10 are allowed to be in contact with the lead frames 51 to 54 of the connector 50 to ensure a heat dissipation path to the mounting substrate in the host device. However, since the signal terminals P and the lead frames 51 to 54 have point-to-point contacts, the heat dissipation efficiency is not very good.

On the other hand, the test terminals T of the memory device 10 are directly connected to, for example, the controller 17 and the like of the memory device 10, and are concentrated on the bonded region A1 of a certain size in which the signal terminal P is not present. The test terminals T are covered with the TIM 20 as the mask sheet to prevent accessing from outside the controller 17. This TIM 20 is bonded to the bonded region A1 of the certain size. Therefore, this TIM 20 can be used as a heat dissipation surface.

In particular, according to the first embodiment, the TIM 20 having a higher thermal conductivity than a thermal conductivity of polycarbonate is used as the mask sheet. The polycarbonate as a material of the mask sheet has a high insulating property, but the thermal conductivity is as low as 0.2 W/(m·K). On the other hand, the TIM 20 has, for example, a thermal conductivity of about 1.0 W/(m·K) to 8.0 W/(m·K) or larger than 8.0 W/(m·K). This allows the memory device 10 to efficiently dissipate heat by a method such as surface contact with the contact region A2 of the printed circuit board 40 on which the connector 50 is mounted via the TIM 20. Further, when a metallic solid pattern or the like connected to the grounding electrode is formed on the contact region A2, heat dissipation effect can be further improved.

### Second Embodiment

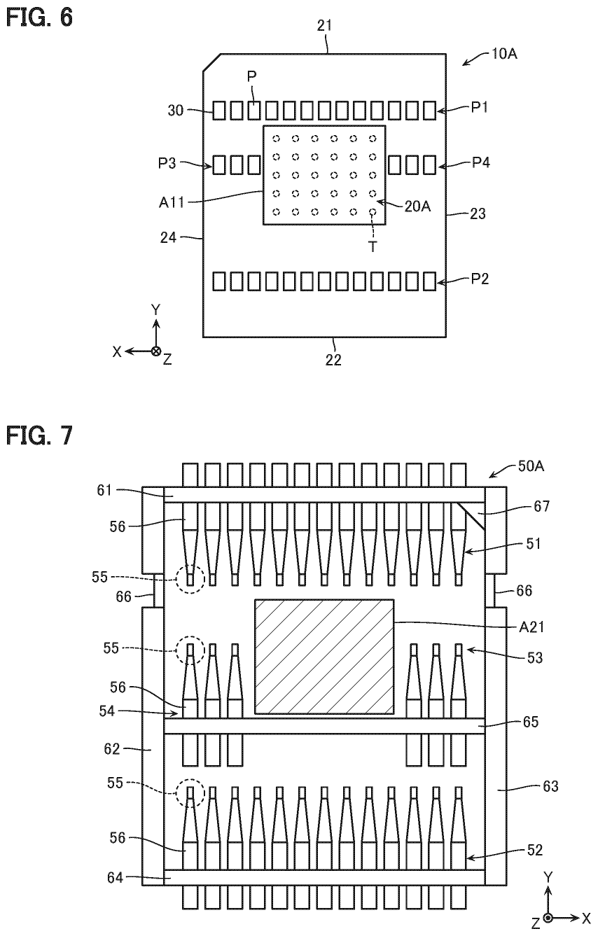

FIG. 6 is a plan view illustrating an outer shape of a memory device 10A according to a second embodiment and a bonded region A11 to which a TIM 20A is bonded. FIG. 7 is a plan view also illustrating an outer shape of a connector 50A and a contact region A21 on the printed circuit board (the mounting substrate) in contact with the TIM 20A.

The memory device 10A illustrated in FIG. 6 is different from the memory device 10 illustrated FIG. 1A, FIG. 1B, and FIG. 1C in that positions of the third signal terminals P3 and the fourth signal terminals P4 at a center in the Y-direction are positioned closer to the first signal terminals P1 than the second signal terminals P2, positions of the test terminals T and the TIM 20A are closer to the first signal terminals P1 than the second signal terminals P2, and the plurality of test terminals T are arranged at equal intervals in each of 5 rows in the Y-direction and 6 columns in the X-direction.

The connector 50A illustrated in FIG. 7 is different from the connector 50 illustrated in FIG. 3 in that the tip sides of the contact portions 55 of the lead frames 53 at a center in the Y-direction are oriented to the lead frame 51 side with respect to the base sides, and the contact region A21 is formed between the lead frame 51 and the connecting portion 65.

According to the second embodiment, the bonded region A11 where the TIM 20A of the memory device 10A is bonded can be further brought close to the controller 17 (FIG. 2). A heat dissipation area can also be increased. Therefore, with the second embodiment, the heat dissipation efficiency can be further improved than the first embodiment.

### Third Embodiment

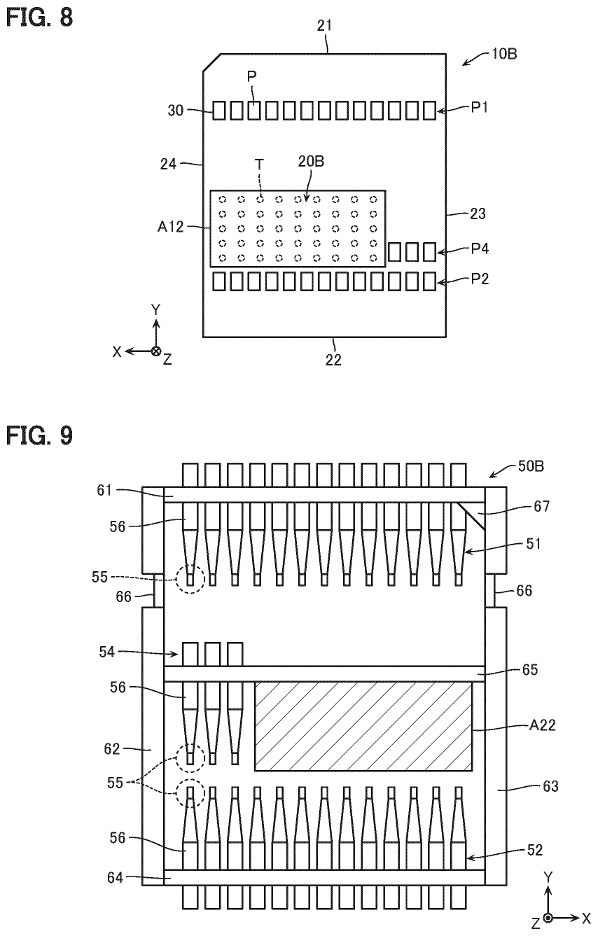

FIG. 8 is a plan view illustrating an outer shape of a memory device 10B according to a third embodiment and a bonded region A12 where a TIM 20B is bonded. FIG. 9 is a plan view also illustrating an outer shape of a connector 50B and a contact region A22 on the printed circuit board (the mounting substrate) in contact with the TIM 20B.

The memory device 10B illustrated in FIG. 8 is different from the memory device 10 illustrated in FIG. 1A, FIG. 1B and FIG. 1C in that the signal terminals at a center in the Y-direction are a plurality of fourth signal terminals P4 alone, the regions of the test terminals T and the TIM 20B are expanded to a position close to the second side surface 24, and the test terminals T are arranged at equal intervals in each of 5 rows in the Y-direction and 9 columns in the X-direction.

The connector 50B illustrated in FIG. 9 is different from the connector 50 illustrated in FIG. 3 in that the lead frames at a center in the Y-direction are the lead frames 54 on one side in the X-direction alone, and the contact region A22 is expanded to a position close to the third wall portion 63.

According to the third embodiment, the heat dissipation area can be further increased than the first embodiment and the second embodiment because the bonded region A12 in which the test terminals T and the TIM 20B of the memory device 10B are arranged is expanded to one side in the X-direction. Thus, the heat dissipation efficiency can be further improved.

### Fourth Embodiment

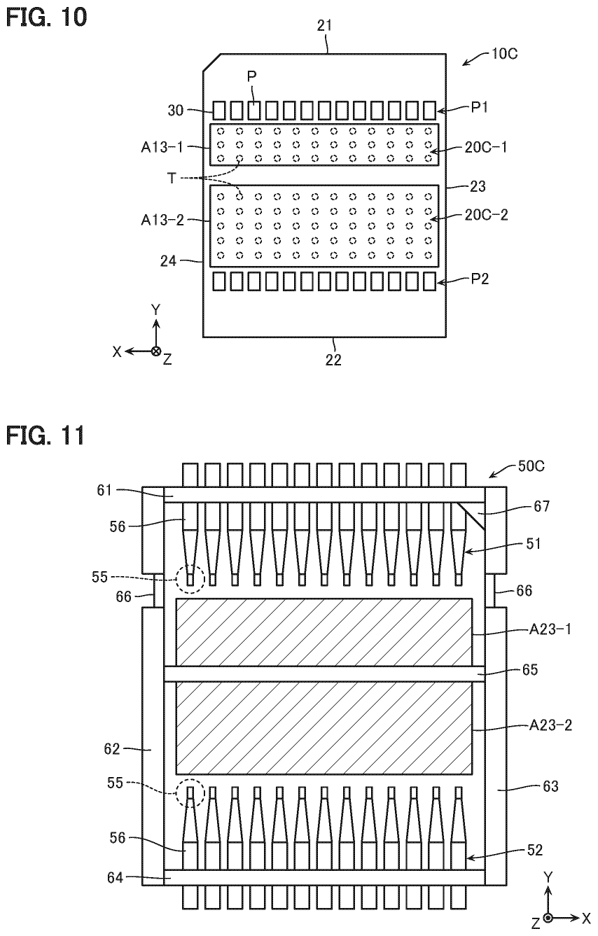

FIG. 10 is a plan view illustrating an outer shape of a memory device 10C according to a fourth embodiment and a bonded region A13-1 and a bonded region A13-2 to which TIMs 20C-1 and 20C-2 are bonded. FIG. 11 is a plan view illustrating an outer shape of a connector 50C and a contact region A23-1 and a contact region A23-2 on the printed circuit board (the mounting substrate) in contact with the TIMs 20C-1 and 20C-2.

The memory device 10C illustrated in FIG. 10 is different from the memory device 10 illustrated in FIG. 1A, FIG. 1B, and FIG. 1C in that the memory device 10C includes the first signal terminals P1 and the second signal terminals P2 alone as the signal terminals P, three rows and twelve columns of the test terminals T and five rows and twelve columns of the test terminals T are placed between the first signal terminals P1 and the second signal terminals P2 to fill a width in the X-direction, and the bonded region A13-1 for bonding the TIM 20C-1 and the bonded region A13-2 for bonding the TIM 20C-2 are each provided on a region where these test terminals T are arranged.

The connector 50C illustrated in FIG. 11 is different from the connector 50 illustrated in FIG. 3 in that the connector 50C includes the lead frames 51 and 52 on both sides in the Y-direction alone as the lead frames, the contact region A23-1 is provided between the lead frames 51 and the connecting portion 65 to fill a width in the X-direction, and the contact region A23-2 is provided between the connecting portion 65 and the lead frames 52 to fill a width in the X-direction.

According to the fourth embodiment, the heat dissipation area can be further increased than the first embodiment to the third embodiment because the bonded regions A13-1 and A13-2 in which the test terminals T and the TIMs 20C-1 and 20C-2 of the memory device 10C are arranged is expanded to both sides in the X-direction. Thus, the heat dissipation efficiency can be further improved.

### Fifth Embodiment

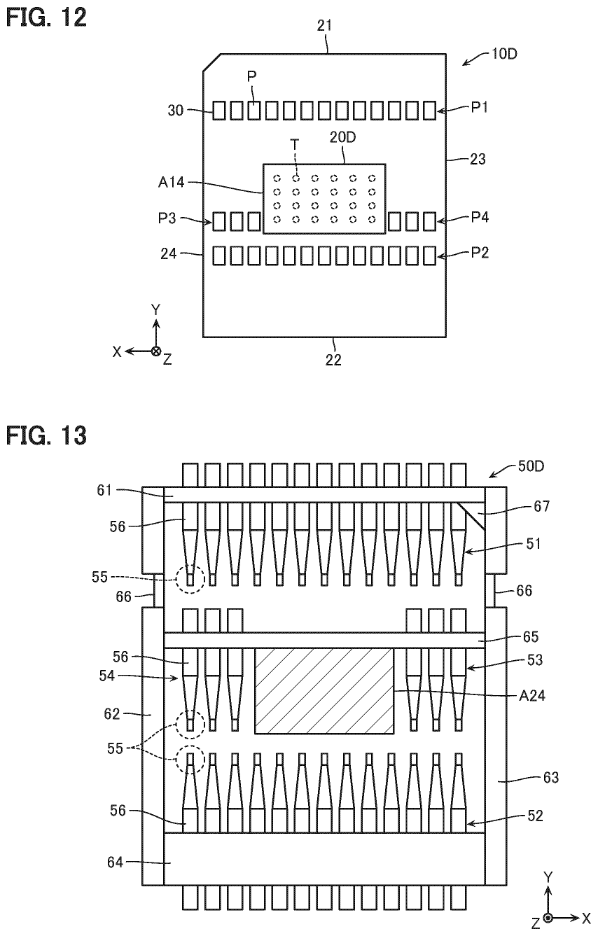

FIG. 12 is a plan view illustrating an outer shape of a memory device 10D according to a fifth embodiment and a bonded region A14 to which a TIM 20D is bonded. FIG. 13 is a plan view also illustrating an outer shape of a connector 50D and a contact region A24 on the printed circuit board (the mounting substrate) in contact with the TIM 20D.

The memory device 10D illustrated in FIG. 12 is different from the memory device 10 illustrated in FIG. 1A, FIG. 1B and FIG. 1C in that the second signal terminals P2, the third signal terminals P3, the fourth signal terminals P4, the test terminals T, the TIM 20D, and the bonded region A14 are brought closer to the first signal terminals P1 and farther away from the second end surface 22 than the first embodiment.

The connector 50D illustrated in FIG. 13 is different from the connector 50 illustrated in FIG. 3 in that the lead frames 53 and 54, the connecting portion 65, and the contact region A24 are brought closer to the lead frames 51 than the first embodiment, and lengths in the Y-direction of the lead frames 52 and the fourth wall portion 64 are longer than those of the first embodiment.

According to the fifth embodiment, similarly to the second embodiment, a heat dissipation portion can be made closer to the controller 17 (FIG. 2). Thus, the heat dissipation efficiency can be improved.

### Sixth Embodiment

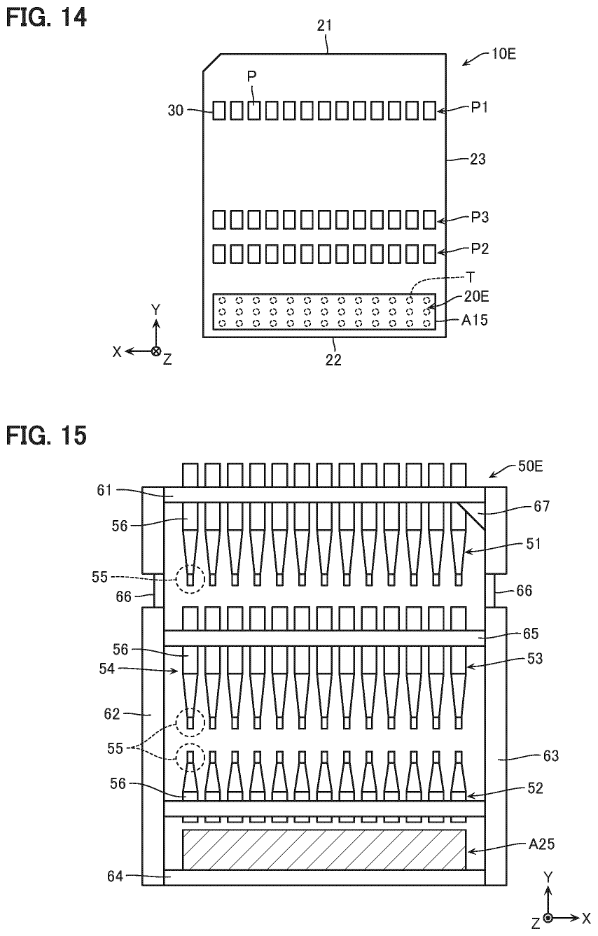

FIG. 14 is a plan view illustrating an outer shape of a memory device 10E according to a sixth embodiment and a bonded region A15 to which a TIM 20E is bonded. FIG. 15 is a plan view also illustrating an outer shape of a connector 50E and a contact region A25 on the printed circuit board (the mounting substrate) in contact with the TIM 20E.

The memory device 10E illustrated in FIG. 14 is different from the memory device 10 illustrated in FIG. 1A, FIG. 1B and FIG. 1C in that the same number of the third signal terminals P3 as these signal terminals P1 and P2 are provided between the first signal terminals P1 and the second signal terminals P2, and the test terminals T, the TIM 20E, and the bonded region A15 are formed between the second signal terminals P2 and the second end surface 22 to fill a width in the X-direction.

The connector 50E illustrated in FIG. 15 is different from the connector 50 illustrated in FIG. 3 in that between the lead frames 51 and 52, the same number of the lead frames 53 as these lead frames 51 and 52 are arranged, and between the lead frames 52 and the fourth wall portion 64, the contact region A25 is formed to fill a width in the X-direction.

According to the sixth embodiment, a heat dissipation site may be provided at an end of the memory device 10E and the connector 50E in the Y-direction. In the sixth embodiment, the bonded region A15 of the TIM 20E is provided between the second signal terminals P2 and the second end surface 22, but the bonded region A15 of the TIM 20E may be provided between the first signal terminals P1 and the first end surface 21.

In this embodiment, a NAND flash memory has been described as an example of a nonvolatile memory. However, the function of this embodiment can also be applied to various other non-volatile memories such as a phase change random access memory (PRAM), a resistive random access memory (ReRAM), a magnetoresistive random access memory (MRAM), or a ferroelectric random access memory (FeRAM).

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate having a first plane and a second plane positioned at an opposite side of the first plane;
a plurality of memory chips mounted on the first plane of the substrate;
a controller mounted on the first plane of the substrate to control the plurality of memory chips;
a plurality of terminals provided on the second plane of the substrate and including a plurality of test terminals;
a sealing member sealing the first plane of the substrate, the plurality of memory chips, and the controller;
a sheet covering the plurality of test terminals among the plurality of terminals, wherein
the sheet is an insulator and has a thermal conductivity of from 1.0 W/(m·K) to 8.0 W/(m·K).

2. The semiconductor memory device according to claim 1, wherein
the sheet is configured to allow to be in contact with a mounting substrate of a connector that is electrically connected to a terminal other than the plurality of test terminals, among the plurality of terminals.

3. The semiconductor memory device according to claim 1, wherein
the outer shape of the semiconductor memory device that is defined by the substrate and the sealing member has a rectangular card shape with a first width in a first direction, a first length in a second direction intersecting with the first direction, and a first thickness in a third direction intersecting with the first direction and the second direction, and
the outer shape of the semiconductor memory device that is defined by the substrate and the sealing member has a first end surface extending in the first direction and the third direction, a second end surface positioned on an opposite side in the second direction of the first end surface and extending in the first direction and the third direction, a first side surface extending in the second direction and the third direction, and a second side surface positioned on an opposite side in the first direction of the first side surface and extending in the second direction and the third direction.

4. The semiconductor memory device according to claim 3, wherein
the plurality of terminals include a plurality of first signal terminals and a plurality of second signal terminals used for signal transmission,
the plurality of first signal terminals are closer to the first end surface than the second end surface and are arranged at first intervals with one another in the first direction, and
the plurality of second signal terminals are closer to the second end surface than the first end surface and are arranged at second intervals with one another in the first direction.

5. The semiconductor memory device according to claim 4, wherein
a distance in the second direction between the plurality of first signal terminals and the plurality of second signal terminals is longer than a distance in the second direction between the plurality of first signal terminals and the first end surface, and longer than a distance in the second direction between the plurality of second signal terminals and the second end surface.

6. The semiconductor memory device according to claim 4, wherein
at least a part of the plurality of test terminals is provided in a region between the plurality of first signal terminals and the plurality of second signal terminals.

7. The semiconductor memory device according to claim 4, wherein
at least a part of the plurality of test terminals is provided in at least one of a region between the plurality of first signal terminals and the first end surface and a region between the plurality of second signal terminals and the second end surface.

8. The semiconductor memory device according to claim 4, wherein
the plurality of terminals include a plurality of third signal terminals used for signal transmission,
the plurality of third signal terminals are provided between the plurality of first signal terminals and the plurality of second signal terminals, and are arranged at third intervals with one another in the first direction,
a number of the plurality of third signal terminals is less than a number of the plurality of first signal terminals and less than a number of the plurality of second signal terminals,
at least a part of the plurality of test terminals is arranged with the plurality of third signal terminals in the first direction.

9. The semiconductor memory device according to claim 8, wherein
the plurality of third signal terminals are closer to the first end surface than the second end surface and farther from the first end surface than the plurality of first signal terminals.

10. The semiconductor memory device according to claim 8, wherein
the plurality of third signal terminals are closer to the second end surface than the first end surface and farther from the second end surface than the plurality of second signal terminals.

11. The semiconductor memory device according to claim 9, wherein
the plurality of terminals include a plurality of fourth signal terminals used for signal transmission,
the plurality of fourth signal terminals are arranged with the plurality of third signal terminals in the first direction and arranged at fourth intervals with one another in the first direction,
at least a part of the plurality of test terminals is provided between the plurality of third signal terminals and the plurality of fourth signal terminals.

12. The semiconductor memory device according to claim 11, wherein
a number of the plurality of third signal terminals and a number of the plurality of fourth signal terminals are equal.

13. The semiconductor memory device according to claim 11, wherein
a number of the plurality of third signal terminals and a number of the plurality of fourth signal terminals are different.

14. A semiconductor memory device comprising:
a substrate having a first plane and a second plane positioned on an opposite side of the first plane;
a plurality of memory chips mounted on the first plane of the substrate;
a controller mounted on the first plane of the substrate to control the plurality of memory chips;
a plurality of terminals provided on the second plane of the substrate and including a plurality of test terminals;
a sealing member sealing the first plane of the substrate, the plurality of memory chips, and the controller;
a sheet covering the plurality of test terminals among the plurality of terminals, wherein
the sheet is configured to allow to be in contact with a mounting substrate of a connector that is electrically connected to a terminal other than the plurality of test terminals, among the plurality of terminals.

15. The semiconductor memory device according to claim 14, wherein
the outer shape of the semiconductor memory device defined by the substrate and the sealing member: has a rectangular card shape with a first width in a first direction, a first length in a second direction intersecting with the first direction, and a first thickness in a third direction intersecting with the first direction and the second direction; and
has a first end surface extending in the first direction and the third direction, a second end surface positioned on an opposite side in the second direction of the first end surface and extending in the first direction and the third direction, a first side surface extending in the second direction and the third direction, and a second side surface positioned on an opposite side in the first direction of the first side surface and extending in the second direction and the third direction.

16. The semiconductor memory device according to claim 15, wherein
the plurality of terminals include a plurality of first signal terminals and a plurality of second signal terminals used for signal transmission,
the plurality of first signal terminals are closer to the first end surface than the second end surface and are arranged at first intervals with one another in the first direction, and
the plurality of second signal terminals are closer to the second end surface than the first end surface and are arranged at second intervals with one another in the first direction.

17. The semiconductor memory device according to claim 16, wherein
a distance in the second direction between the plurality of first signal terminals and the plurality of second signal terminals is longer than a distance in the second direction between the plurality of first signal terminals and the first end surface, and longer than a distance in the second direction between the plurality of second signal terminals and the second end surface.

18. The semiconductor memory device according to claim 16, wherein
at least a part of the plurality of test terminals is provided in a region between the plurality of first signal terminals and the plurality of second signal terminals.

19. The semiconductor memory device according to claim 16, wherein
at least a part of the plurality of test terminals is provided in at least one of a region between the plurality of first signal terminals and the first end surface and a region between the plurality of second signal terminals and the second end surface.

20. The semiconductor memory device according to claim 16, wherein
the plurality of terminals include a plurality of third signal terminals used for signal transmission,
the plurality of third signal terminals are provided between the plurality of first signal terminals and the plurality of second signal terminals, and are arranged at third intervals with one another in the first direction,
a number of the plurality of third signal terminals is less than a number of the plurality of first signal terminals and less than a number of the plurality of second signal terminals,
at least a part of the plurality of test terminals is arranged with the plurality of third signal terminals in the first direction.
